(19) United States
(12) Patent Application Publication
(10) Pub. No.: US 2010/0148745 A1
(43) Pub. Date: Jun. 17, 2010

(54) Wireless Communication Apparatus

(75) Inventor: Hideto Kanou, Kanagawa (JP)

Correspondence Address: HOGAN & HARTSON L.L.P., 1999 AVENUE OF THE STARS, SUITE 1400, LOS ANGELES, CA, 90067, US

(73) Assignee: KYOCERA CORPORATION, Kyoto-shi, Kyoto (JP)

(21) Appl. No.: 12/528,772

(22) PCT Filed: Feb. 26, 2008
(86) PCT No.: PCT/JP2008/053299

§ 371 Date: Dec. 17, 2009

(30) Foreign Application Priority Data
Feb. 27, 2007 (JP) 2007-047349

(51) Int. Cl. G05F 3/00; H03G 3/20

(52) U.S. Cl. 323/318; 330/127

(57) ABSTRACT

In a wireless communication apparatus of the present invention for transmitting a modulated signal using multi-carriers, a bias voltage of a power amplifier (101) for amplifying the modulated signal is controlled by control units (10, 102) according to the number of carriers in the modulated signal so as to reduce power consumption.

### CROSS REFERENCE TO RELATED APPLICATION

This application claims priority to and the benefit of Japanese Patent Application No. 2007-47349 filed on Feb. 27, 2007, the entire contents of which are incorporated herein by reference.

### TECHNICAL FIELD

The present invention relates to a wireless communication apparatus adopting a modulation scheme using a number of carriers (hereinafter, appropriately referred to as a multi-carriers).

### BACKGROUND ART

Presently, a so-called wireless broadband having a large communication capacity has been considered actively in a wireless communication field. A known system as one of systems of the wireless broadband is WiMAX (Worldwide Interoperability for Microwave Access), for example, which is defined in IEEE (Institute of Electrical and Electronic Engineers) 802.16 standard (for example, see Non-Patent Document 1).

WiMAX system adopts OFDM (Orthogonal Frequency Division Multiplexing) using multi-carriers as a modulation scheme. In addition, IEEE802.16e standard provided with mobility adopts OFDMA (Orthogonal Frequency Division Multiple Access) as a multiple access scheme.

FIG. 4 is a block diagram illustrating a schematic configuration of a power amplifier module of a conventional wireless communication apparatus adopting OFDM.

A power amplifier module 100 shown in FIG. 4 has a power amplifier element 101 constituting a power amplifier and a bias circuit 102 thereof. When a voltage V_batt is applied from a battery to a power supply terminal 113 as a power supply voltage and a necessary bias voltage is applied from the bias circuit 102 to the power amplifier element 101, the power amplifier element 101 amplifies an OFDM signal PA_IN input from an input terminal 111 to a prescribed power and outputs an output signal PA_OUT to an output terminal 112.

When a control signal PA_ON of a positive level is input through a bias control terminal 114, the bias circuit 102 is turned on and supplies the power amplifier element 101 with a bias voltage generated based on a reference voltage V_Ref supplied to a reference voltage terminal 115. The bias voltage to be supplied to the power amplifier element 101 is set so that the OFDM signal output by the power amplifier element 101 fulfills the standard.

When a control signal of a zero level is input through the bias control terminal 114, the bias circuit 102 is turned off and stops supplying the bias voltage to the power amplifier element 101 so as to set the power amplifier element 101 inactive.

Non-Patent Document 1: Takeshi Hattori and Masanobu Fujioka, “Impress Standard Textbook Series, Wireless Broadband Textbook revised edition, High Speed IP Wireless Edition” first edition, Impress R&D Company, June 2006, pages 199-212

### SUMMARY OF INVENTION

### Technical Problem

The power amplifier element 101 for amplifying the OFDM signal shown in FIG. 4 is required to have a high linearity, since it is necessary to prevent degradation of a modulation accuracy (EVM: Error Vector Magnitude) caused by intermodulation components and the likes so as to fulfill the standard of the system.

In addition, PAPR (Peak to Average Power Ratio) of the OFDM signal increases in proportion to the number of carriers. For example, PAPR of the OFDM signal with a channel bandwidth of 5 MHz and an FFT (Fast Fourier Transform) size of 512 points, as defined in IEEE802.16e, is approximately 10 dB. However, PAPR of a OFDM signal with a channel bandwidth of 10 MHz and a FFT size of 1024 points reaches approximately 13 dB. In this manner, PAPR increases in proportion to the channel bandwidth and the FFT size.

Thus, in order to fulfill the standard with obtaining the linearity in a peak power, it is necessary to apply a larger current as the peak power, i.e., the number of carriers, increases.

Incidentally, for example, for OFDMA of the multiple access scheme adopted by IEEE802.16e, as shown as an example of a frame structure in FIG. 5, the number of carriers in uplink (Uplink (up)) on the terminal side is appropriately determined according to conditions such as an application, traffic and the likes to be less than the maximum number of carriers. It is to be noted that a horizontal axis and a vertical axis indicate time and frequency, respectively, in FIG. 5.

As set forth above, since PAPR declines as the number of carriers being used decreases, it is possible to obtain the linearity of a power amplifier element with a smaller current.

In the power amplifier module 100 of the conventional wireless communication apparatus shown in FIG. 4, however, the bias voltage of the power amplifier element 101 is fixed to a voltage where the OFDM signal fulfills the standard, that is, the voltage corresponding to the usable maximum number of carriers, and the power supply voltage of the power amplifier element 101 is fixed to the battery voltage V_batt.

Consequently, a large idle current always flows even when a small number of carriers are being used, which leads to an increase in power consumption. Such increase in power consumption results in shortening of the usable time of a battery of a mobile wireless communication apparatus using the battery as its power source in particular.

Thus, an object of the present invention in consideration of such a circumstance is to provide a wireless communication apparatus using a multicarrier modulation scheme capable of reducing power consumption.

### Solution to Problem

In order to achieve the above object, a wireless communication apparatus for transmitting a modulated signal using multi-carriers in accordance with a first aspect of the present invention includes:

a power amplifier for amplifying the modulated signal; and

a control unit for controlling a bias voltage of the power amplifier according to the number of carriers in the modulated signal.

A second aspect of the present invention is that the wireless communication apparatus in accordance with the first aspect is further provided with a memory unit for storing a value of the bias voltage of the power amplifier corresponding to the number of carriers,

wherein the control unit controls the bias voltage of the power amplifier based on the value of the bias voltage corresponding to the number of carriers stored in the memory unit.

A third aspect of the present invention is that, in the wireless communication apparatus in accordance with the first aspect,

the control unit controls the bias voltage of the power amplifier according to the number of carriers and transmission power for transmitting the modulated signal.

A fourth aspect of the present invention is that the wireless communication apparatus in accordance with the third aspect is further provided with a memory unit for storing a value of the bias voltage of the power amplifier corresponding to the number of carriers and the transmission power,

wherein the control unit controls the bias voltage of the power amplifier based on the value of the bias voltage corresponding to the number of carriers and the transmission power stored in the memory unit.

Moreover, in order to achieve the above object, a wireless communication apparatus for transmitting a modulated signal using multi-carriers in accordance with a fifth aspect of the present invention includes:

a power amplifier for amplifying the modulated signal;

a DC/DC converter for supplying the power amplifier with a power supply voltage; and

a control unit for controlling an output voltage of the DC/DC converter according to the number of carriers in the modulated signal.

A sixth aspect of the present invention is that the wireless communication apparatus in accordance with the fifth aspect is further provided with a memory unit for storing a value of the power supply voltage of the power amplifier corresponding to the number of carriers,

wherein the control unit controls the output voltage of the DC/DC converter based on the value of the power supply voltage corresponding to the number of carriers stored in the memory unit.

A seventh aspect of the present invention is that, in the wireless communication apparatus in accordance with the fifth aspect,

the control unit controls the output voltage of the DC/DC converter according to the number of carriers and transmission power for transmitting the modulated signal.

An eighth aspect of the present invention is that the wireless communication apparatus in accordance with the seventh aspect is further provided with a memory unit for storing a value of the power supply voltage of the power amplifier corresponding to the number of carriers and the transmission power,

wherein the control unit controls the output voltage of the DC/DC converter based on the value of the power supply voltage of the power amplifier corresponding to the number of carriers and the transmission power stored in the memory unit.

### ADVANTAGEOUS EFFECTS ON INVENTION

According to the present invention, since a bias voltage or a power supply voltage of a power amplifier for amplifying a modulated signal on multi-carriers is controlled according to the number of carriers in the modulated signal, it is possible to supply an optimum bias voltage or a power supply voltage to the power amplifier. Thereby, it enables a reduction of power consumption of a wireless communication apparatus.

### BRIEF DESCRIPTION OF DRAWINGS

FIG. 1 is a block diagram illustrating a schematic configuration of a power amplifier module of a wireless communication apparatus in accordance with a first embodiment of the present invention;

FIG. 2 is a block diagram illustrating a schematic configuration of a power amplifier module of a wireless communication apparatus in accordance with a second embodiment of the present invention;

FIG. 3 is a diagram for explaining threshold information stored in a memory unit shown in FIG. 2;

FIG. 4 is a block diagram illustrating a schematic configuration of a power amplifier module of a conventional wireless communication apparatus; and

FIG. 5 is a diagram illustrating an example of a frame structure of OFDMA.

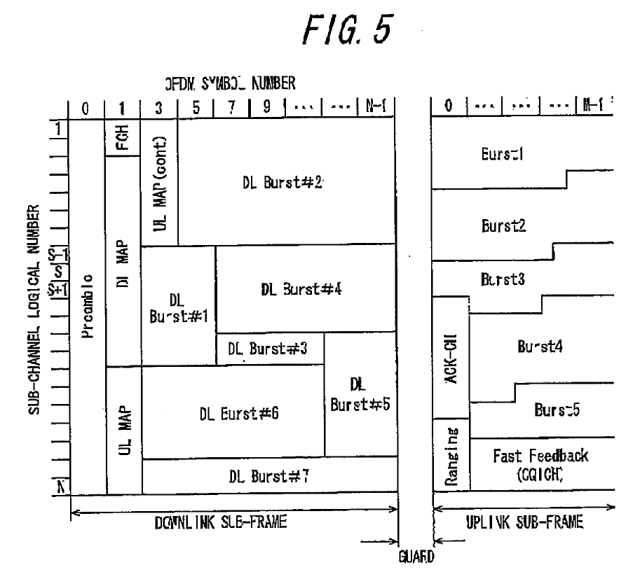

### REFERENCE SIGNS LIST

1, 2 power amplifier module
10 bias circuit control unit
11, 22 memory unit
20 DC/DC converter
21 converter control unit
101 power amplifier element
102 bias circuit
111 input terminal
112 output terminal
113 power supply terminal
114 bias control terminal
115 reference voltage terminal

### DESCRIPTION OF EMBODIMENTS

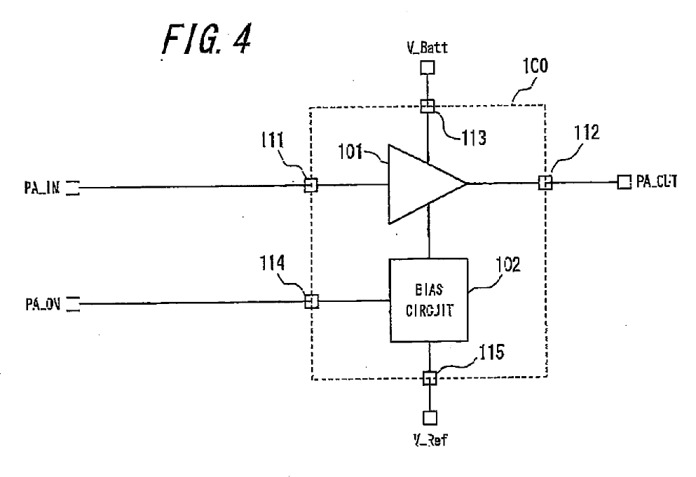

Embodiments of the present invention will be described with reference to the accompanying drawings. It is to be noted that elements with functions the same as those of the elements in FIG. 4 are given identical reference signs and detailed explanations thereof will be omitted.

### First Embodiment

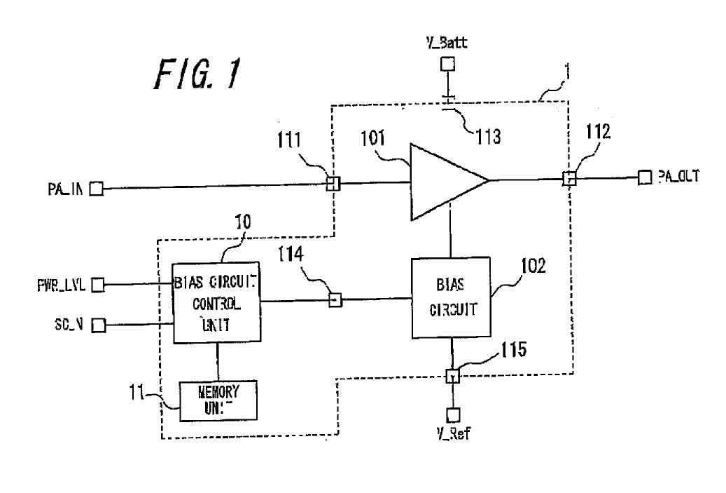

FIG. 1 is a block diagram illustrating a schematic configuration of a power amplifier module of a wireless communication apparatus for transmitting a modulated signal using multi-carriers in accordance with a first embodiment of the present invention. A power amplifier module 1 for amplifying the modulated signal is provided with a power amplifier element 101 constituting a power amplifier, a bias circuit 102, a bias circuit control unit 10 for controlling the bias circuit 102, and a memory unit 11 serving as a storing unit.

The bias circuit control unit 10 is supplied with information on the number of carriers SC_N and information on transmission power PWR_LVL in a multicarrier modulated signal from an upper communication control unit (not shown). In addition, the memory unit 11 preliminarily stores a bias voltage table for determining a value of a bias voltage to be supplied to the power amplifier element 101 correspondingly to the number of carriers and the transmission power.

Table 1 shows an example of the bias voltage table stored in the memory unit 11. As shown in Table 1, the value of the bias voltage is set to be smaller in proportion to reductions in the number of carriers and the transmission power.

TABLE 1

| | Bias Voltage [V] | | |
|---|---|---|---|
| | Transmission | | |
| | Power [dBm] | | |
| The Number of Carriers | <10 | 10~15 | 15< |
| ~50 | 1.0 | 1.0 | 1.2 |
| 51~200 | 1.0 | 1.2 | 1.5 |
| 201~ | 1.2 | 1.5 | 2.0 |

In FIG. 1, based on the information on the number of carriers SC_N and the information on the transmission power PWR_LVL in the modulated signal input from the upper communication control unit, the bias circuit control unit 10 reads out a corresponding value of the bias voltage from the bias voltage table stored in the memory unit 11. The bias circuit control unit 10 then supplies the corresponding value of the bias voltage to the bias circuit 102 via a bias control terminal 114. Thereby, the bias circuit control unit 10 controls the bias circuit 102 so that the bias voltage to be applied from the bias circuit 102 to the power amplifier element 101 corresponds to the value of the bias voltage read out from the memory unit 11. Consequently, the bias circuit control unit 10 and the bias circuit 102 constitute a control unit in the present embodiment.

According to the present embodiment, a bias voltage supplied to the power amplifier element 101 is determined according to the number of carriers and transmission power to be lower in proportion to the reductions in the number of carriers and the transmission power. Hence, it is possible to improve efficiency of the power amplifier element 101 and reduce power consumption, which is favorable particularly for the wireless communication apparatus for which duration of a battery becomes an issue.

### Second Embodiment

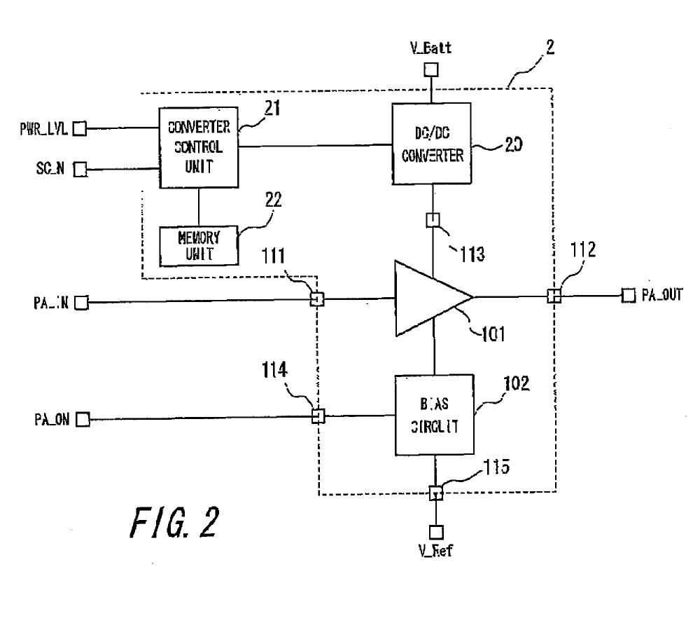

FIG. 2 is a block diagram illustrating a schematic configuration of a power amplifier module of a wireless communication apparatus for transmitting a modulated signal using multi-carriers in accordance with a second embodiment of the present invention. A power amplifier module 2 for amplifying the modulated signal is provided with a power amplifier element 101 constituting a power amplifier, a bias circuit 102 thereof, a DC/DC converter 20 for applying a necessary power supply voltage to the power amplifier element 101, a converter control unit 21 for controlling an output voltage of the DC/DC converter 20, and a memory unit 22.

The DC/DC converter 20 converts an input voltage, a battery voltage V_Batt, into a necessary voltage under the control of the converter control unit 21. The output voltage of the DC/DC converter 20 is applied to a power supply terminal 113 as the power supply voltage for the power amplifier element 101.

In a similar manner to the first embodiment, the converter control unit 21 is supplied with information on the number of carriers SC_N and information on the transmission power PWR_LVL in the multicarrier modulated signal from an upper communication control unit (not shown). In addition, the memory unit 22 preliminarily stores a value of the power supply voltage to be applied to the power supply terminal 113 of the power amplifier element 101, that is, a value of the output voltage of the DC/DC converter 20, correspondingly to the number of carriers and the transmission power in the modulated signal.

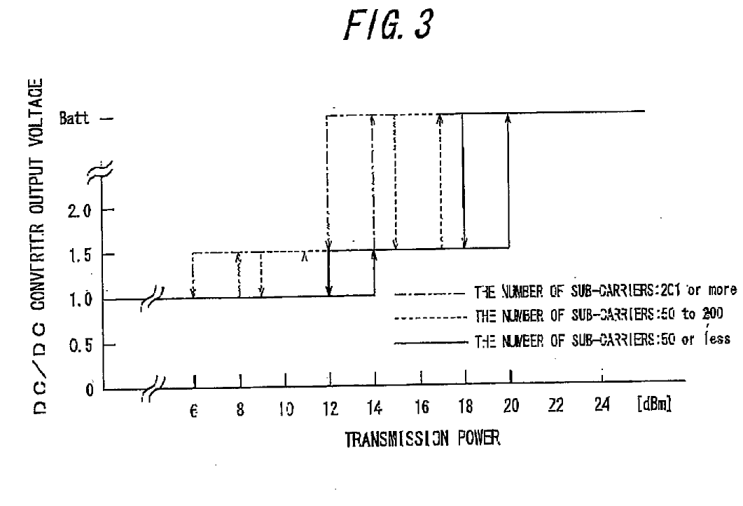

As shown in FIG. 3, for example, the value of the output voltage of the DC/DC converter 20 stored in the memory unit 22 is set to be smaller in proportion to the reductions in the number of carriers (sub-carriers) and the transmission power. In particular, the value of the output voltage of the DC/DC converter 20 is set to be changed according to the transmission power as indicated by an alternate long and short dash line when the number of carriers is 201 or more, a dashed line when the number of carriers is 51 to 200, or a solid line when the number of carriers is 50 or less. It is to be noted that the values of the output voltages have hysteresis properties when the transmission power is increased and when the transmission power is decreased in the present embodiment.

In FIG. 2, based on the information on the number of carriers SC_N and the information on the transmission power PWR_LVL input from the upper communication control unit, the converter control unit 21 reads out a corresponding value of the power supply voltage from the memory unit 22 and supplies it to the DC/DC converter 20. Thereby, the converter control unit 21 controls the DC/DC converter 20 so that the output voltage of the DC/DC converter 20 corresponds to the value of the power supply voltage read out from the memory unit 22. Consequently, the DC/DC converter 20 and the converter control unit 21 constitute a control unit in the present embodiment.

According to the present embodiment, the power supply voltage lower than the battery voltage V_Batt is supplied to the power supply terminal 113 of the power amplifier element 101 in proportion to the reductions in the number of carriers and the transmission power. In a similar manner as the first embodiment, it is thus possible to improve efficiency of the power amplifier element 101 and reduce power consumption, which is favorable particularly for the wireless communication apparatus for which the duration of the battery becomes the issue.

It is to be understood that the present invention is not limited to the embodiments described above and various modification and changes may be made. For example, although the bias voltage is controlled in stages according to the number of carriers and the transmission power in the first embodiment described above, it is possible to control the bias voltage continuously. In addition, it is also possible to control the bias voltage of the first embodiment and the power supply voltage (the output voltage of the DC/DC converter 20) of the second embodiment according only to the number of carriers without considering the transmission power, so as to be lower in proportion to a reduction in the number of carriers.

1. A wireless communication apparatus for transmitting a modulated signal using multi-carriers comprising:
a power amplifier for amplifying the modulated signal; and
a control unit for controlling a bias voltage of the power amplifier according to the number of carriers in the modulated signal.

2. The wireless communication apparatus according to claim 1, further comprising a memory unit for storing a value of the bias voltage of the power amplifier corresponding to the number of carriers,
wherein the control unit controls the bias voltage of the power amplifier based on the value of the bias voltage corresponding to the number of carriers stored in the memory unit.

3. The wireless communication apparatus according to claim 1, wherein the control unit controls the bias voltage of the power amplifier according to the number of carriers and transmission power for transmitting the modulated signal.

4. The wireless communication apparatus according to claim 3, further comprising a memory unit for storing a value of the bias voltage of the power amplifier corresponding to the number of carriers and the transmission power,
wherein the control unit controls the bias voltage of the power amplifier based on the value of the bias voltage corresponding to the number of carriers and the transmission power stored in the memory unit.

5. A wireless communication apparatus for transmitting a modulated signal using multi-carriers comprising:
a power amplifier for amplifying the modulated signal;
a DC/DC converter for supplying the power amplifier with a power supply voltage; and
a control unit for controlling an output voltage of the DC/DC converter according to the number of carriers in the modulated signal.

6. The wireless communication apparatus according to claim 5, further comprising a memory unit for storing a value of the power supply voltage of the power amplifier corresponding to the number of carriers,
wherein the control unit controls the output voltage of the DC/DC converter based on the value of the power supply voltage corresponding to the number of carriers stored in the memory unit.

7. The wireless communication apparatus according to claim 5, wherein the control unit controls the output voltage of the DC/DC converter according to the number of carriers and transmission power for transmitting the modulated signal.

8. The wireless communication apparatus according to claim 7, further comprising a memory unit for storing a value of the power supply voltage of the power amplifier corresponding to the number of carriers and the transmission power,
wherein the control unit controls the output voltage of the DC/DC converter based on the value of the power supply voltage of the power amplifier corresponding to the number of carriers and the transmission power stored in the memory unit.
